(19) United States
(12) Patent Application Publication
(10) Pub. No.: US 2025/0351730 A1
(43) Pub. Date: Nov. 13, 2025

(54) METHOD FOR MANUFACTURING PIEZOELECTRIC FILM, PIEZOELECTRIC FILM MANUFACTURED BY THE METHOD, AND PIEZOELECTRIC DEVICE

(71) Applicant: Murata Manufacturing Co., Ltd., Nagaokakyo-shi (JP)

(72) Inventors: Takahiko YANAGITANI, Tokyo (JP); Shinya KUDO, Tokyo (JP); Sota KUNINOBU, Tokyo (JP); Shiori KOBAYASHI, Tokyo (JP); Hiromu OKUNAGA, Nagaokakyo-shi (JP)

(21) Appl. No.: 19/278,442

(22) Filed: Jul. 23, 2025

Related U.S. Application Data
(63) Continuation of application No. PCT/JP2024/000878, filed on Jan. 15, 2024.

(30) Foreign Application Priority Data
Jan. 25, 2023 (JP) 2023-009599

(51) Int. Cl. H10N 30/853; H10N 30/093; H10N 30/50

(52) U.S. Cl. CPC H10N 30/8542; H10N 30/093; H10N 30/50

(57) ABSTRACT

A method for manufacturing a piezoelectric film including a monocrystalline or polycrystalline piezoelectric material in which a particular oriented crystal axis is inclined from a direction perpendicular or substantially perpendicular to the film, includes preparing a substrate including a single crystal with a same rotational symmetry about a particular substrate crystal axis as a rotational symmetry about the particular oriented crystal axis in the piezoelectric material, and the particular substrate crystal axis has a same inclination as an inclination of the particular oriented crystal axis, and forming a piezoelectric film including the piezoelectric material on the substrate by an epitaxial process.

### CROSS REFERENCE TO RELATED APPLICATIONS

This application claims the benefit of priority to Japanese Patent Application No. 2023-009599 filed on Jan. 25, 2023 and is a Continuation Application of PCT Application No. PCT/JP2024/000878 filed on Jan. 15, 2024. The entire contents of each application are hereby incorporated herein by reference.

### BACKGROUND OF THE INVENTION

### 1. Field of the Invention

The present invention relates to methods for manufacturing piezoelectric films each for use, for example, in frequency filters used in communication devices such as smartphones.

### 2. Description of the Related Art

A frequency filter including a piezoelectric film, such as a surface acoustic wave (SAW) filter that uses surface acoustic waves generated on the surface of a piezoelectric film or a bulk acoustic wave (BAW) filter that uses a vibration in the bulk of a piezoelectric film, has conventionally been used as a frequency filter which allows passage therethrough of electrical signals in a particular frequency band. The SAW filter and the BAW filter use a monocrystalline or polycrystalline piezoelectric film, which is oriented in a particular direction, in order to align directions in which piezoelectricity is generated.

Japanese Unexamined Patent Application Publication No. 2021-153263 describes a BAW filter including a piezoelectric film including a single crystal of lithium niobate (LiNbO₃). Lithium niobate has a trigonal crystal structure having a three-fold rotational symmetry about the c-axis. A lithium niobate film can generate higher piezoelectricity in a direction perpendicular to the film when the c-axis is oriented in a direction inclined from a direction perpendicular to the film than when the c-axis is oriented perpendicular to the film. Therefore, the BAW filter described in Japanese Unexamined Patent Application Publication No. 2021-153263 uses a piezoelectric film obtained by cutting a bulk single crystal of lithium niobate into a plate shape such that the c-axis is inclined from a direction perpendicular to the film.

Many piezoelectric films have been produced directly (without performing a cutting operation) in the form of a film by using a sputtering method or the like. If a lithium niobate film, whose c-axis is inclined from a direction perpendicular to the film, can be obtained using such a method, there is no need for a cutting operation, enabling easy production of the film. In fact, however, the use of a sputtering method to produce a lithium niobate film results in the formation of a film whose c-axis is directed in a direction perpendicular to the film (see, for example, Japanese Unexamined Patent Application Publication No. 2008-013824). Thus, it is not possible to obtain a lithium niobate film whose c-axis is inclined from a direction perpendicular to the film.

The problem involved in obtaining a piezoelectric film, whose c-axis is inclined from a direction perpendicular to the film in order to increase the piezoelectricity in the direction perpendicular to the film, has been described using lithium niobate as an example. On the other hand, in the case of piezoelectric materials such as scandium aluminum nitride (ScAlN) and magnesium zinc oxide (MgZnO), a piezoelectric film is used in which a particular axis (c-axis of hexagonal crystal) is inclined from a direction perpendicular to the film in order to generate high piezoelectricity in a direction parallel to the film so that a shear vibration will be generated in the direction parallel to the film. The production of such a piezoelectric film involves the same problem as described above for a lithium niobate piezoelectric film.

### SUMMARY OF THE INVENTION

Example embodiments of the present invention provide methods for manufacturing monocrystalline or polycrystalline piezoelectric films, in each of which a predetermined crystal axis is inclined in a particular direction from a direction perpendicular or substantially perpendicular to the film, without performing an operation to cut a bulk single crystal into a film.

A method for manufacturing a piezoelectric film including a monocrystalline or polycrystalline piezoelectric material in which a particular oriented crystal axis is inclined from a direction perpendicular to the film, the method including preparing a substrate including a single crystal with a same or substantially a same rotational symmetry about a particular substrate crystal axis as a rotational symmetry about a particular oriented crystal axis in the piezoelectric material, the particular substrate crystal axis including a same inclination as an inclination of the particular oriented crystal axis, and forming a piezoelectric film including the piezoelectric material on the substrate by an epitaxial process.

In a piezoelectric film manufacturing method according to an example embodiment of the present invention, a rotational symmetry about a particular oriented crystal axis of a piezoelectric film to be manufactured is matched with a rotational symmetry about a particular substrate crystal axis of a substrate. In other words, a substrate including a material whose crystal structure has such a rotational symmetry is used. In addition, the substrate is prepared such that a direction of the particular substrate crystal axis is aligned with a direction of the particular oriented crystal axis so that the particular oriented crystal axis of the piezoelectric film to be manufactured and the particular substrate crystal axis of the substrate have the same inclination. In forming a piezoelectric film including the piezoelectric material on such a substrate by an epitaxial process, the piezoelectric film grows such that the film is aligned with the single crystal of the substrate, and such that the particular oriented crystal axis is directed in the same direction as the particular substrate crystal axis. Thus, it is possible to obtain a monocrystalline or polycrystalline piezoelectric film in which the particular oriented crystal axis is inclined in a particular direction from a direction perpendicular or substantially perpendicular to the film.

When manufacturing a piezoelectric film having a three-fold rotational symmetry about the particular oriented crystal axis, a substrate can be used which includes a material having a three-fold rotational symmetry or a six-fold rotational symmetry about the particular substrate crystal axis (material having a six-fold rotational symmetry also satisfies a three-fold rotational symmetry). When manufacturing a piezoelectric film having a six-fold rotational symmetry about the particular oriented crystal axis, a substrate is used which includes a material having a six-fold rotational symmetry about the particular substrate crystal axis. When manufacturing a piezoelectric film having a four-fold rotational symmetry about the particular oriented crystal axis, a substrate is used which includes a material having a four-fold rotational symmetry about the particular substrate crystal axis.

For example, when manufacturing a film of lithium niobate, which is a piezoelectric material having a three-fold rotational symmetry about the c-axis, a material with a crystal structure having a three-fold or six-fold rotational symmetry about a particular axis can be used for the substrate. For example, a substrate can be used which includes sapphire (Al₂O₃), silicon carbide (SiC), titanium (Ti), gallium phosphide (GaP), or the like with a trigonal or hexagonal crystal structure having a three-fold or six-fold rotational symmetry about the c-axis. Further, a substrate with the (111) plane as a surface can be used which includes a cubic material such as strontium titanate (SrTiO₃), magnesium oxide (MgO), aluminum (Al), silicon (Si), germanium (Ge), gallium arsenide (GaAs), yttria-stabilized zirconia (YSZ), or the like having a three-fold rotational symmetry about an axis perpendicular to the (111) plane. The same substrates as the above-described substrates can be used to manufacture a film of scandium aluminum nitride or magnesium zinc oxide, which is a piezoelectric materials having a six-fold rotational symmetry about the c-axis.

When manufacturing a film of lead titanate (PTO: PbTiO₃), lead zirconate titanate (PZT: Pb(Zr,Ti)O₃), or the like, which is a piezoelectric material having a four-fold rotational symmetry about the c-axis, a piezoelectric material with a crystal structure having a four-fold rotational symmetry about the c-axis can be used for the substrate. For example, a substrate with the (100) plane as a surface can be used which includes a cubic material such as strontium titanate, magnesium oxide, aluminum, silicon, germanium, gallium arsenide, yttria-stabilized zirconia, or the like having a four-fold rotational symmetry about an axis perpendicular to the (100) plane.

A piezoelectric film manufacturing method according to an example embodiment of the present invention can further include, between the preparing the substrate and the forming the piezoelectric film, forming a conductive film, including a conductive material having the same rotational symmetry about a predetermined crystal axis as a rotational symmetry about the particular substrate crystal axis, on the surface of the substrate by an epitaxial process is performed. Thus, in the forming the piezoelectric film, the piezoelectric film is formed on the surface of the conductive film.

Also in the case where a piezoelectric film is formed on a substrate via such a conductive film, it is possible to obtain a piezoelectric film in which the particular oriented crystal axis is directed in the same direction as the particular substrate crystal axis. In this case, the conductive film can be used as an electrode to apply a voltage to the piezoelectric film.

For example, when a substrate including a material having a three-fold or six-fold rotational symmetry about the c-axis, such as sapphire or silicon carbide, is used in the manufacturing of a film of a piezoelectric material having a three-fold or six-fold rotational symmetry about the c-axis, platinum, which has a three-fold rotational symmetry and a six-fold rotational symmetry about an axis along the [111] direction, can advantageously be used as a material for the conductive film.

The piezoelectric films manufactured by methods according to example embodiments of the present invention are each epitaxially grown such that the particular oriented crystal axis is inclined from a direction perpendicular or substantially perpendicular to the film. When a cross-section of such epitaxially-grown piezoelectric films are each observed by transmission electron microscopy (TEM), the presence of dislocations, which are linear crystal defects, will be observed. Such dislocations are rarely seen in a single crystal of a bulk piezoelectric material, and thus provide evidence of the epitaxial growth of the piezoelectric film.

In a possible construction, for example, the piezoelectric film is in contact with a conductive film including a monocrystalline or polycrystalline conductive material having the same rotational symmetry about a predetermined crystal axis as a rotational symmetry about the particular oriented crystal axis, the predetermined crystal axis having the same inclination as the inclination of the particular oriented crystal axis. Such a construction can be obtained by forming the piezoelectric film on the substrate via the conductive film in a method of according to an example embodiment of the present invention.

When an electric field having an intensity exceeding the coercive electric field is applied to the piezoelectric film, manufactured by a method according to an example embodiment of the present invention, in one direction perpendicular or substantially perpendicular to the film to align polarization components in a direction perpendicular or substantially perpendicular to the film (hereinafter referred to as “perpendicular polarization components”) in the one direction, and then the positive and negative of the applied electric field are reversed (an electric field exceeding the coercive electric field is applied in a 180-degree different direction), the direction of the perpendicular or substantially perpendicular polarization components is reversed in an area of the piezoelectric film, located in the vicinity of the surface opposite from the substrate, while the direction of the perpendicular polarization components is maintained in an area of the piezoelectric film, located in the vicinity of the substrate-side surface. Thus, in the piezoelectric film, a state is achieved in which the perpendicular or substantially perpendicular polarization components are directed in opposite directions between one surface side and the other surface side. Upon stopping the application of the electric field, a piezoelectric film is obtained in which the perpendicular or substantially perpendicular polarization components are directed in opposite directions between the vicinity of one surface and the vicinity of the other surface. Such a piezoelectric film can be used as an oscillator which, upon application of an AC electric field lower than the coercive electric field, expands and contracts in 180-degree different phases between one surface side and the other surface side, and generates a vibration having a wavelength about twice the thickness of the film in a direction perpendicular or substantially perpendicular to the film.

The piezoelectric films manufactured by methods according to example embodiments of the present invention can each be used as a piezoelectric film for a piezoelectric device such as a BAW device, an SAW device, a Lamb wave device, or the like, which is to be used, for example, in a frequency filter. The BAW device propagates sound waves in the film thickness direction, and includes an SMR (Solidly Mounted Resonator) device in which a piezoelectric film is provided on a Bragg reflector, an FBAR (Film Bulk Acoustic Resonator) device in which a self-supported piezoelectric film is sandwiched between electrodes, an XBAR (Excited Bulk Wave Resonator) device in which comb-shaped electrodes are provided on a self-supported piezoelectric film, etc. The SAW device includes comb-shaped electrodes provided on a piezoelectric film on a substrate, and propagates sound waves in a direction parallel or substantially parallel to the surface of the film. The Lamb wave device includes comb-shaped electrodes provided on a self-supported piezoelectric film, and propagate sound waves in a direction parallel or substantially parallel to the surface of the film. The piezoelectric films manufactured by methods according to example embodiments of the present invention can each also be provided in other known piezoelectric devices.

According to example embodiments of the present invention, it is possible to manufacture monocrystalline or polycrystalline piezoelectric films, in each of which a predetermined crystal axis is inclined in a particular direction from a direction perpendicular or substantially perpendicular to the film, without performing an operation for cutting a bulk single crystal into a film.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1A is a schematic vertical cross-sectional view illustrating a substrate preparation step in example embodiment 1 of a piezoelectric film manufacturing method according to the present invention.

FIG. 1B is a schematic vertical cross-sectional view illustrating a conductive film forming step in example embodiment 1 of the present invention.

FIG. 1C is a schematic vertical cross-sectional view illustrating a piezoelectric film forming step in example embodiment 1 of the present invention.

FIG. 1D is a schematic vertical cross-sectional view illustrating a conductive film forming step in example embodiment 1 of the present invention.

FIG. 2 is a schematic vertical cross-sectional view illustrating a piezoelectric film forming step in a variation of example embodiment 1 of the present invention.

FIG. 3 is a graph showing the results of X-ray diffraction measurement as performed by 2θ-ω scan on a piezoelectric film of lithium niobate, manufactured by the method of example embodiment 1, and on a reference film.

FIG. 4 is a graph showing the results of X-ray diffraction measurement as performed by ω scan (2θ fixed) on a piezoelectric film of lithium niobate, manufactured by the method of example embodiment 1, and on a reference film.

FIG. 5A is a (10-12) plane pole figure obtained by X-ray diffractometry of a piezoelectric film of lithium niobate, having an inclination angle α of about 10°, manufactured by the method of example embodiment 1 of the present invention.

FIG. 5B is a (10-12) plane pole figure obtained by X-ray diffractometry of a piezoelectric film of lithium niobate, having an inclination angle α of about 20°, manufactured by the method of example embodiment 1 of the present invention.

FIG. 6 is a graph showing measured conversion loss values and a theoretical curve of conversion loss for a thin-film resonator obtained using a piezoelectric film of lithium niobate, having an inclination angle α of about 10°, manufactured by the method of example embodiment 1, and also showing those for a thin-film resonator obtained using a reference piezoelectric film.

FIG. 7 is a hysteresis curve showing the results of measurement of the minimum value of conversion loss, performed at varying intensities of applied DC electric field, for a piezoelectric film of lithium niobate, having an inclination angle α of about 20°, manufactured by the method of example embodiment 1 of the present invention.

FIG. 8A is a (10-11) plane pole figure obtained by X-ray diffractometry of a piezoelectric film of scandium aluminum nitride, having an inclination angle α of about 10°, manufactured by the method of example embodiment 1 of the present invention.

FIG. 8B is a (10-11) plane pole figure obtained by X-ray diffractometry of a piezoelectric film of magnesium zinc oxide, having an inclination angle α of about 20°, manufactured by the method of example embodiment 1 of the present invention.

FIG. 9A is a transmission electron microscope photograph of a piezoelectric film of magnesium zinc oxide, having an inclination angle α of about 20°, manufactured by the method of example embodiment 1 of the present invention.

FIG. 9B is an electron diffraction image obtained in a piezoelectric film of magnesium zinc oxide, having an inclination angle α of about 20°, manufactured by the method of example embodiment 1 of the present invention.

FIG. 10A is a graph showing measured conversion loss values and a theoretical curve of conversion loss for a thin-film resonator obtained using a piezoelectric film of scandium aluminum nitride, having an inclination angle α of about 10°, manufactured by the method of example embodiment 1 of the present invention.

FIG. 10B is a graph showing measured conversion loss values and a theoretical curve of conversion loss for a thin-film resonator obtained using a piezoelectric film of magnesium zinc oxide, having an inclination angle α of about 20°, manufactured by the method of example embodiment 1 of the present invention.

FIG. 11 is a graph showing the results of X-ray diffraction measurement as performed by 2θ-ω scan on a piezoelectric film of lanthanum-doped strontium titanate, having an inclination angle α of about 25°, manufactured by the method of example embodiment 1 of the present invention.

FIG. 12 is a (101) plane pole figure obtained by X-ray diffractometry of a piezoelectric film of lanthanum-doped strontium titanate, having an inclination angle α of about 25°, manufactured by the method of example embodiment 1 of the present invention.

FIG. 13 is a graph showing an impulse response of a thin-film resonator obtained using a piezoelectric film of lanthanum-doped strontium titanate, having an inclination angle α of about 25°, manufactured by the method of example embodiment 1 of the present invention.

FIG. 14A is a graph showing measured longitudinal wave conversion loss values and a theoretical curve of longitudinal wave conversion loss for a thin-film resonator obtained using a piezoelectric film of lanthanum-doped strontium titanate, having an inclination angle α of about 25°, manufactured by the method of example embodiment 1 of the present invention.

FIG. 14B is a graph showing measured transversal wave conversion loss values and a theoretical curve of transversal wave conversion loss for a thin-film resonator obtained using a piezoelectric film of lanthanum-doped strontium titanate, having an inclination angle α of about 25°, manufactured by the method of example embodiment 1 of the present invention.

FIG. 15 is a cross-sectional view of a piezoelectric device according to example embodiment 2 of the present invention.

FIG. 16A is a graph showing the relationship between the second Euler angle and a coupling coefficient as observed when the piezoelectric film of the piezoelectric device according to example embodiment 2 of the present invention includes lithium tantalate.

FIG. 16B is a graph showing the relationship between the second Euler angle and a coupling coefficient as observed when the piezoelectric film of the piezoelectric device according to example embodiment 2 of the present invention includes lithium niobate.

FIG. 16C is a graph showing the relationship between the second Euler angle and the SH wave/Rayleigh wave ratio in the piezoelectric device according to example embodiment 2 of the present invention.

FIG. 17 is a cross-sectional view of a piezoelectric device according to a variation of example embodiment 2 of the present invention.

### DETAILED DESCRIPTION OF THE EXAMPLE EMBODIMENTS

Example embodiments of the present invention will be described in detail below with reference to the drawings.

### Example Embodiment 1

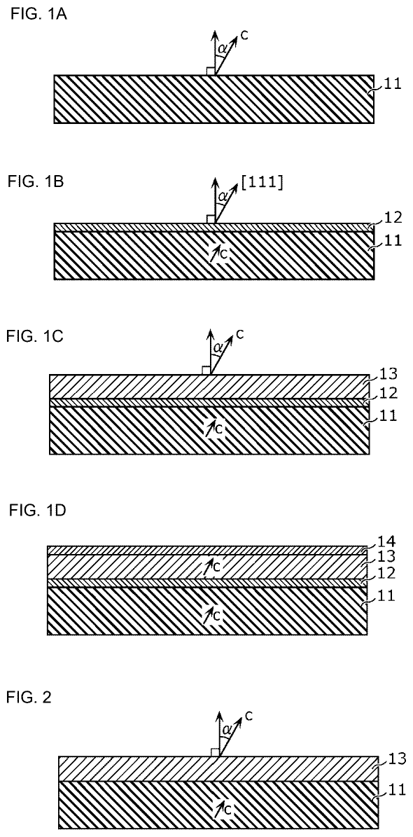

A piezoelectric film manufacturing method according to example embodiment 1 of the present invention and a piezoelectric film manufactured by the method will be described with reference to FIGS. 1A through 14.

### (1) Procedure of the Piezoelectric Film Manufacturing Method of Example Embodiment 1

A description is first provided of a case of manufacturing a piezoelectric film including lithium niobate in which the c-axis, which is a particular oriented crystal axis, is inclined with respect to a direction perpendicular or substantially perpendicular to the film. First, a sapphire substrate 11 is prepared. The crystal of sapphire is hexagonal and has a six-fold rotational symmetry about the c-axis. The c-axis of the sapphire is a particular substrate crystal axis. The substrate 11 is produced by cutting a single crystal of sapphire such that the inclination direction of the c-axis of sapphire, which is an insulating material, coincides with the inclination direction of the c-axis of a piezoelectric film to be manufactured on the substrate 11 (FIG. 1A: substrate preparation step). The single crystal of sapphire can be cut by a cutting device using a laser beam or a diamond wire saw, for example. Since the substrate 11 is sufficiently thicker than the piezoelectric film 13 to be manufactured, an operation for cutting the single crystal of sapphire to produce the substrate 11 is easier than an operation for cutting a single crystal of a piezoelectric material into a film (plate). Instead of sapphire, for example, a substrate including silicon carbide or the like, having a crystal structure with a six-fold rotational symmetry about the c-axis, may be used.

In the following description, “α” denotes the angle that the particular substrate crystal axis forms with a normal to the surface of the substrate 11. The angle α is determined such that the inclination direction of the particular substrate crystal axis matches the inclination direction of the particular oriented crystal axis of a piezoelectric film to be manufactured. The angle α is determined within the range of more than 0° and less than 90° so that the inclination angle of the particular oriented crystal axis meets the piezoelectric characteristics required for a piezoelectric film to be manufactured. When manufacturing a piezoelectric film including lithium niobate as in the present example embodiment, the piezoelectricity in a direction perpendicular or substantially perpendicular to the film can be made higher when the c-axis is inclined by, for example about 10° to about 30° with respect to a direction perpendicular or substantially perpendicular to the film than when the c-axis is perpendicular or substantially perpendicular to the film. Therefore, the angle α is, for example, preferably made within the range of about 10° to about 30°. When it is intended to make the piezoelectricity high in a direction other than a direction perpendicular or substantially perpendicular to the film, for example in the case of generating a shear vibration, in a piezoelectric film including lithium niobate, the angle α may be outside the range of about 10° to about 30°.

Next, for example, a film including platinum is epitaxially grown on the surface of the substrate 11 to form a conductive film 12 (FIG. 1B: conductive film forming step). The crystal of platinum has a face-centered cubic lattice structure and has a six-fold rotational symmetry about an axis in the [111] direction. When platinum is epitaxially grown on the surface of the substrate 11 including a sapphire single crystal whose c-axis is inclined by a with respect to a direction perpendicular made to the film, the platinum crystal grows such that the [111] direction of platinum is aligned with the c-axis direction of the sapphire of the substrate 11, such that a conductive film 12 of platinum is formed which includes, for example, a single crystal facing in the same direction (α direction) or a polycrystal oriented in the same direction. Instead of platinum, for example, a metal having a face-centered cubic lattice crystal structure, such as gold, aluminum, copper, silver, or iridium, may be used as the material of the conductive film 12.

Next, a film including lithium niobate is epitaxially grown on the surface of the conductive film 12 to form a piezoelectric film 13 (FIG. 1C: piezoelectric film forming step). The crystal of lithium niobate is trigonal and has a three-fold rotational symmetry and a six-fold rotational symmetry about the c-axis. When lithium niobate is epitaxially grown on the surface of the conductive film 12 including platinum, whose crystal has grown such that the [111] direction is aligned with the c-axis direction of the sapphire of the substrate 11, the lithium niobate crystal grows such that the c-axis of lithium niobate is aligned with the c-axis of sapphire and with the [111] direction of platinum. As a result, a piezoelectric film 13 is obtained in which the c-axis of lithium niobate is inclined by an angle α with respect to a direction perpendicular or substantially perpendicular to the film.

The conductive film 12 defines and functions as one of a pair of electrodes used to apply a voltage to the piezoelectric film 13 in the thickness direction, or to detect a voltage generated in the thickness direction of the piezoelectric film 13 by polarization. When such a conductive film 12 is provided on one side (the substrate 11 side) of the piezoelectric film 13 in the thickness direction, a second conductive film 14 including a conductive material, which defines and functions as the other electrode, is formed on the piezoelectric film 13 (on the opposite side from the substrate 11) (FIG. 1D: second conductive film forming step). The second conductive film 14 need not necessarily be grown epitaxially, and may be formed by a common method such as vapor deposition, for example.

When the conductive film 12 is not necessary, a film including lithium niobate may be epitaxially grown directly on the surface of the substrate 11 (FIG. 2). Also in this case, the c-axis of lithium niobate is directed in the same direction as the c-axis of the substrate 11. Thus, a piezoelectric film 13, in which the c-axis is inclined by the angle α with respect to a direction perpendicular or substantially perpendicular to the film, can be obtained.

The conductive film 12 and the piezoelectric film 13 can be produced by an epitaxial process which uses, for example, a magnetron sputtering apparatus and in which the film forming rate is adjusted by appropriately setting the input power, the film forming temperature, etc. Specific examples of the power, the film forming temperature, etc. will be described later.

While the method of the present example embodiment has been described with reference to the case where the piezoelectric material of the piezoelectric film 13 is lithium niobate, the same method can be used to manufacture a piezoelectric film including other piezoelectric material. For example, when manufacturing a piezoelectric film composed of a piezoelectric material having a hexagonal crystal structure, such as aluminum nitride (AlN), scandium aluminum nitride (ScAlN), zinc oxide (ZnO), or magnesium zinc oxide (MgZnO), a substrate including sapphire, silicon carbide, or the like, having a six-fold rotational symmetry about the c-axis, may be used as in the above-described example embodiment. For example, when manufacturing a piezoelectric film including a piezoelectric material having a crystal structure with a four-fold rotational symmetry about the c-axis, such as lead titanate (PbTiO₃), a substrate including strontium titanate (SrTiO₃), having a four-fold rotational symmetry about the c-axis, can be used.

### (2) Manufacturing Conditions for Piezoelectric Films Manufactured by the Method of Example Embodiment 1, and Experimental Results for the Piezoelectric Films

A description will now be provided of manufacturing conditions and experimental results for some piezoelectric films manufactured using the method of the present example embodiment.

### (2-1) Lithium Niobate

Three types of piezoelectric films 13 including lithium niobate, respectively having aimed inclination angles α of the c-axis (particular oriented crystal axis) of about 10°, about 20°, and about 30° with respect to the direction perpendicular or substantially perpendicular to the film, were manufactured. Substrates 11 including a single crystal of sapphire were produced by cutting the single crystal such that the c-axis (particular substrate crystal axis) of the sapphire was inclined by about 10°, about 20°, and about 30°, respectively, from a normal to the surface of the substrate 11. In the manufacturing of any of the three types of exemplary piezoelectric films, a conductive film 12 including platinum was formed on the substrate 11, and then the piezoelectric film 13 was formed on the conductive film 12. An RF (radio frequency) magnetron sputtering apparatus was used to form the conductive film 12 and the piezoelectric film 13. The film forming conditions are as follows.

### Conductive Film 12 of Platinum

A platinum target was placed on a cathode of the RF magnetron sputtering apparatus, and a film was formed to a thickness of about 50 nm at a temperature of about 680° C. in an argon gas atmosphere at a pressure of about 0.5 Pa while applying a radio-frequency power of about 80 W.

### Piezoelectric Film 13 of Lithium Niobate

A target, including a powder mixture of a powder of simple lithium powder and a powder of simple niobium at an atomic ratio of about 65:35, was placed on the cathode, and a film was formed at a temperature of about 650° C. while applying a radio-frequency power of about 100 W in a mixed gas atmosphere at a pressure of about 0.5 Pa. The mixed gas was a mixture of argon gas and oxygen gas at a partial pressure ratio of about 15:1. The thickness of the piezoelectric film 13 formed was about 2400 nm in the case of α=about 10°, about 900 nm in the case of α=about 20°, and about 1500 nm in the case of α=about 30°. For reference, a reference piezoelectric film including lithium niobate having an aimed inclination angle α of about 0° was formed to a thickness of about 900 nm under the same or substantially the same conditions as in the above-described three examples using a substrate in which the c-axis of sapphire was directed in the normal direction of the surface. In the anticipation that lithium will partially sublime from the piezoelectric film 13 during the formation of the piezoelectric film 13, the abundance ratio (about 65/35) of lithium to niobium in the target was made higher than that (about 1/1) in lithium niobate.

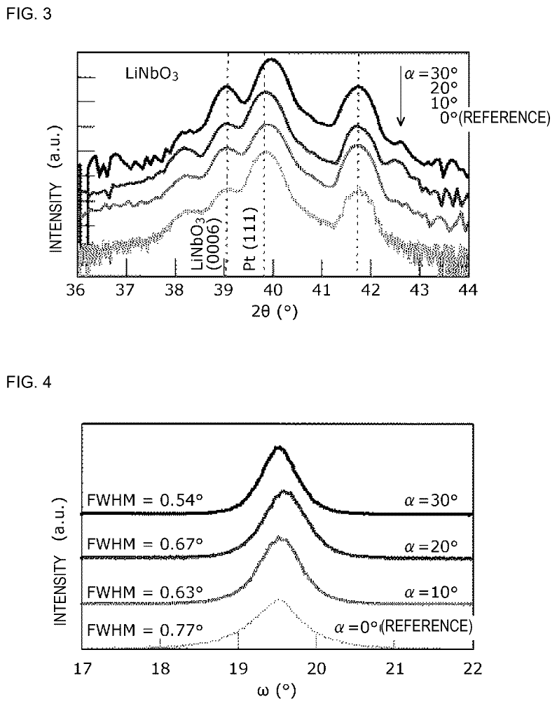

X-ray diffraction measurement was performed on the three piezoelectric films 13 of the present example embodiment and on the reference piezoelectric film. First, a 2θ-ω scan, ω representing the incident angle of X-rays incident on the surface of each piezoelectric film, and 2θ representing the angle between the incident X-rays and exiting X-rays detected by a detector, was performed by varying ω and 2θ while maintaining ω=θ. The results are shown in FIG. 3. In FIG. 3, the data of the 2θ-ω scans for the four piezoelectric films are shifted in the ordinate axis direction so as to avoid overlapping as much as possible. In all the cases of α=about 0°, about 10°, about 20°, and about 30°, a diffraction peak due to the (0006) plane of lithium niobate is seen at 2θ=about 39.1° or its vicinity. The peaks, each seen at 2θ=about 40° or its vicinity, is a diffraction peak due to the (0006) plane of the sapphire of the substrate 11.

Next, an ω scan was performed by fixing 2θ at about 39.1° and varying only ω. As a result, as shown in FIG. 4, a peak was obtained at ω=about 19.5°-about 19.6° or its vicinity in all the cases where the aimed inclination angles α were about 0°, about 10°, about 20°, and about 30°. The fact that a peak is obtained in an ω scan of a piezoelectric film 13 indicates that the piezoelectric film 13 is a single crystal or a polycrystal in which the directions of (0001) planes are aligned in a direction (in the case of a non-oriented polycrystal in which the directions of (0001) planes are not aligned in a direction, X-rays are detected in a ω scan regardless of the value of ω). The full widths at half maximum of the peaks in the ω scan were about 0.63°, about 0.67°, and about 0.54° when α=1 about 0°, about 20°, and about 30°, respectively, which were smaller than the full width at half maximum of about 0.77° when α=about 0°. This indicates that the piezoelectric films 13, obtained by the method of the present example embodiment, have good crystallinity at least comparable to that of the piezoelectric film obtained by using the substrate having no inclination of the particular substrate crystal axis.

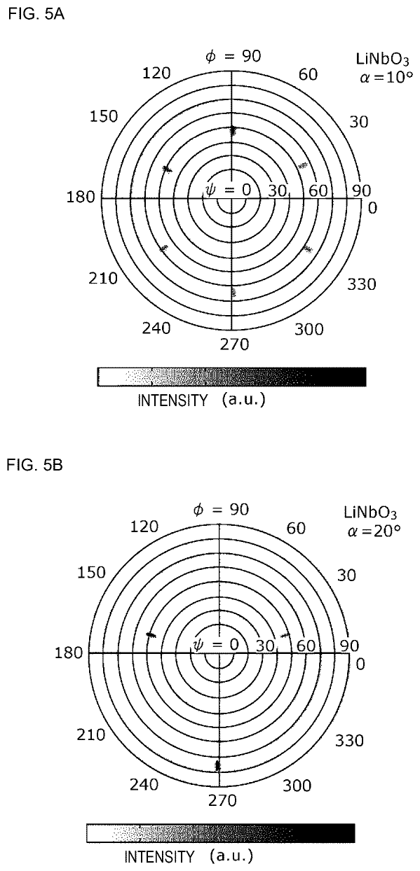

Next, for each of the piezoelectric films 13 having aimed inclination angles α of about 10° and about 20°, a pole figure for the (10-12) plane was obtained by X-ray diffractometry. FIG. 5A shows the pole figure obtained for the piezoelectric film 13 having an inclination angle α of about 10°, and FIG. 5B shows the pole figure obtained for the piezoelectric film 13 having an inclination angle α of about 20°. In FIG. 5B, three poles are seen which show a three-fold rotational symmetry about a point where the deflection angle Ψ is around 20°. This indicates that the piezoelectric film 13 with α=about 20° is oriented such that the direction of the c-axis (particular oriented crystal axis) is inclined at the same inclination angle as the aimed inclination angle, and is also oriented in a direction in a plane perpendicular or substantially perpendicular to the c-axis. On the other hand, in FIG. 5A, six poles are seen which show a six-fold rotational symmetry about a point where the deflection angle Ψ is around 10°. This indicates that while the piezoelectric film 13 with α=about 10° is not oriented in a direction in a plane perpendicular or substantially perpendicular to the c-axis (mixed crystal growth in two directions), the piezoelectric film 13 is oriented such that the direction of the c-axis is inclined at the same or substantially the same inclination angle as the aimed inclination angle.

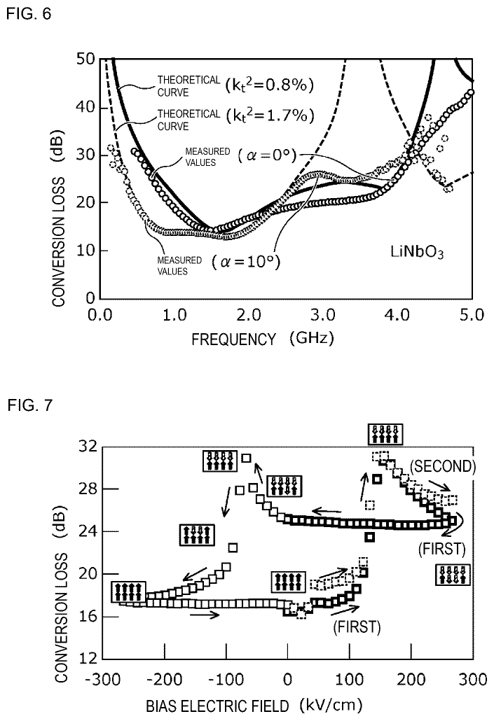

Next, a second conductive film 14 was formed on the piezoelectric film 13, whose c-axis had been confirmed to be oriented such that the inclination angle α was about 10°, to produce a thin-film resonator, and a conversion loss of the resonator was measured using a network analyzer. For reference, the same measurement was performed on the piezoelectric material with α=about 0°. The measurement results are shown in FIG. 6. From a comparison between a conversion loss curve obtained and a theoretical curve of conversion loss calculated using Mason's equivalent circuit model, the electromechanical coupling coefficient kt² in a direction perpendicular or substantially perpendicular to the film can be estimated to be about 0.8% when α=about 0°, and about 1.7% when α=about 10°. The fact that the value of kt² is higher when α=about 10° than when α=about 0° indicates that the piezoelectricity in a direction perpendicular or substantially perpendicular to the film is higher when α=about 10°.

Next, using the piezoelectric film 13 whose c-axis had been confirmed to be oriented such that the inclination angle α was about 20°, a thin-film resonator was produced in the same manner as described above in the case of using the piezoelectric film 13 with α=about 10°, and a conversion loss was measured while applying a DC bias electric field between the conductive film 12 and the second conductive film 14. The DC bias electric field was applied in the range of about −280 to about +280 kV/cm. A positive value of the DC bias electric field indicates that the electric field is positive on the conductive film 12 side, while a negative value of the DC bias electric field indicates that the electric field is negative on the conductive film 12 side. The DC bias electric field was changed from about 0 kV/cm to about +280 kV/cm, then changed from about +280 kV/cm to about −280 kV/cm, and then changed from about −280 kV/cm to about +280 kV/cm. Thus, the measurement was performed twice in the range from about 0 kV/cm to about +280 kV/cm.

The measurement results are shown in FIG. 7. The conversion loss has a local maximum value at a DC bias electric field of about +150 kV/cm, and therefore the coercive electric field of the piezoelectric film 13 is estimated to be about 150 kV/cm. The conversion loss value at a DC bias electric field of about +150 kV/cm corresponds to a value upon the reverse of half of the polarizations formed in the conductive film 12. The direction of the perpendicular or substantially perpendicular polarization components is reversed in an area of the piezoelectric film 13, located in the vicinity of the (second conductive film 14-side) surface on the opposite side from the substrate 11, whereas the direction of the perpendicular or substantially perpendicular polarization components is maintained without reverse in an area of the piezoelectric film 13, located in the vicinity of the substrate 11-side (conductive film 12-side) surface. Further, as shown in FIG. 7, there was no substantial change in the conversion loss during the period from the time when a DC bias electric field of about +280 kV/cm, which is higher than the coercive electric field, was applied to reverse more than half of the polarizations (not all the polarizations were reversed) to the time when the DC bias electric field was decreased to 0. This indicates that the state of polarization before the decrease of the DC bias electric field was substantially maintained. Similarly, when the application of the DC bias electric field is stopped (decreased to 0) from a state in which half of the polarizations have been reversed, the state of polarization will be maintained.

### (2-2) Scandium Aluminum Nitride, Magnesium Zinc Oxide

Scandium aluminum nitride and magnesium zinc oxide both have a wurtzite crystal structure and have a six-fold rotational symmetry about the c-axis. When the c-axis is inclined with respect to a direction perpendicular or substantially perpendicular to the film, a piezoelectric film including any of these materials can generate a thickness-shear mode vibration that vibrates parallel or substantially parallel to the film. In the present example embodiment, a piezoelectric film including scandium aluminum nitride and a piezoelectric film including magnesium zinc oxide, in which the c-axis as a particular oriented crystal axis is inclined with respect to a direction perpendicular or substantially perpendicular to the film, were manufactured for use in a thin-film resonator that generates such a thickness-shear mode vibration.

Two types of substrates 11 including single crystal sapphire, respectively having aimed inclination angles α of about 10° and about 20° (the c-axis of sapphire, which is a particular substrate crystal axis, are inclined by about 10° and about 20° with respect to a normal to the substrate surface), were prepared. A conductive film 12 of platinum was formed on the surface of each of the substrate 11 with α=about 10° and the substrate 11 with α=about 20°. In the case of the substrate 11 with α=about 10°, a piezoelectric film 13 including scandium aluminum nitride was formed on the surface of the conductive film 12. In the case of the substrate 11 with α=about 20°, a piezoelectric film 13 including magnesium zinc oxide was formed on the surface of the conductive film 12. An RF magnetron sputtering apparatus was used to form the conductive films 12 and the two types of piezoelectric films 13. The film forming conditions are as follows.

### Conductive Film 12 of Platinum

A platinum target was placed on a cathode of the RF magnetron sputtering apparatus, and a film was formed to a thickness of about 50 nm at a temperature of about 700° C. in an argon gas atmosphere at a pressure of about 0.5 Pa while applying a radio-frequency power of about 100 W.

### Piezoelectric Film 13 of Scandium Aluminum Nitride

A target, including a simple aluminum plate in which particles of simple scandium were embedded such that the atomic ratio between scandium and aluminum was about 8:92, was placed on the cathode, and a film was formed to a thickness of about 4500 nm at a temperature of about 450° C. in a mixed gas atmosphere at a pressure of about 0.6 Pa while applying a radio-frequency power of about 100 W. The mixed gas was a mixture of argon gas and nitrogen gas at a partial pressure ratio of about 1:3. The atomic ratio between scandium and aluminum in the resulting piezoelectric film 13 was confirmed to be about 8:92.

### Piezoelectric Film 13 of Scandium Aluminum Nitride

A target, including a mixed powder of a magnesium oxide powder and a zinc oxide powder which were mixed such that the atomic ratio between magnesium and zinc was about 30:70, was placed on the cathode, and a film was formed to a thickness of about 6600 nm at a temperature of about 350° C. in a mixed gas atmosphere at a pressure of about 1.0 Pa while applying a radio-frequency power of about 150 W. The mixed gas was a mixture of argon gas and nitrogen gas at a partial pressure ratio of about 20:1.

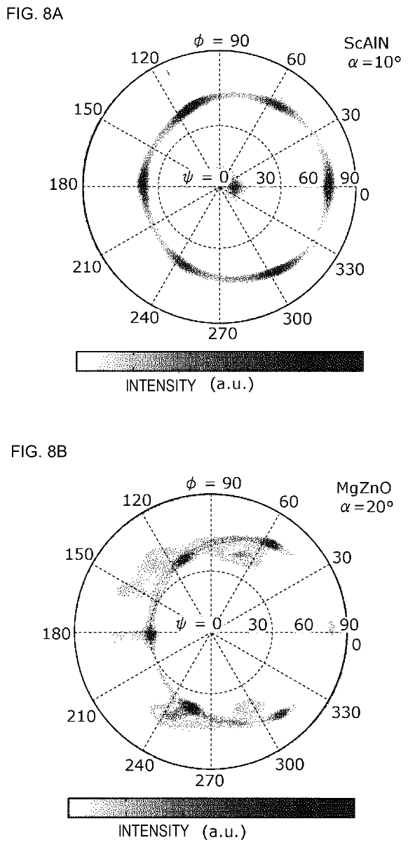

For each of the two types of piezoelectric films 13, a pole figure for the (10-11) plane was obtained by X-ray diffractometry. FIG. 8A shows the pole figure for the piezoelectric film 13 (α=about 10°) of scandium aluminum nitride, and FIG. 8B shows the pole figure for the piezoelectric film 13 (α=about 20°) of magnesium zinc oxide. In FIG. 8A, six poles are seen which show a six-fold rotational symmetry about a point where the deflection angle Ψ is around 10°, and in FIG. 8B, six poles are seen which show a six-fold rotational symmetry about a point where the deflection angle Ψ is around 20°. This indicates that the two types of piezoelectric films 13 are both oriented such that the c-axis direction is inclined at the same or substantially the same inclination angle as the aimed inclination angle.

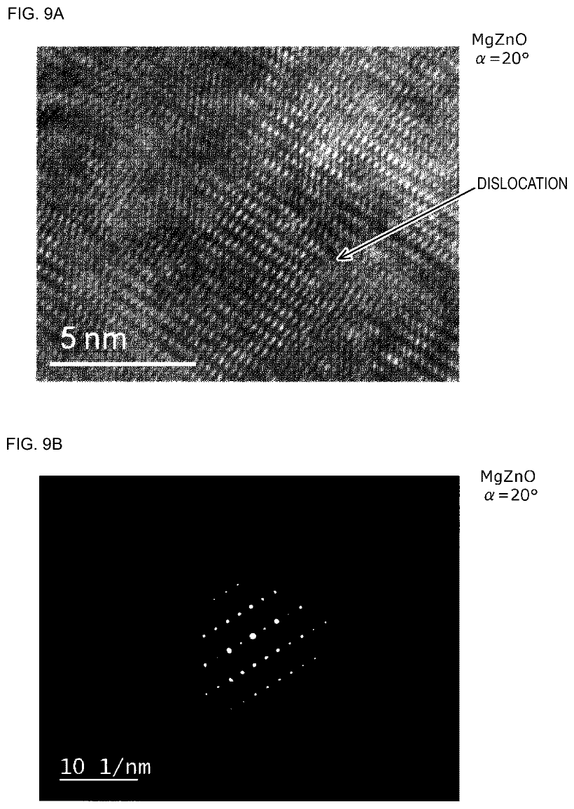

Next, a transmission electron microscope (TEM) photograph of the thus-obtained piezoelectric film 13 including magnesium zinc oxide was taken by an electron beam applied in the [10-11] direction, and an electron diffraction image was obtained. The TEM photograph is shown in FIG. 9A, and the electron diffraction image is shown in FIG. 9B. The TEM photograph shows the state of atoms arranged in a straight line, indicating that the crystal of magnesium zinc oxide crystals has grown in one direction. However, dislocations are seen in places (e.g. at the site shown by the arrow in FIG. 9A). Such dislocations are caused by epitaxial growth. Thus, the presence of dislocations in the piezoelectric film 13 indicates that the piezoelectric film 13 has been formed by an epitaxial process, and that the piezoelectric film 13 has grown epitaxially such that the particular oriented crystal axis, which is a predetermined crystal axis (c-axis), is inclined from a direction perpendicular or substantially perpendicular to the piezoelectric film 13. As used herein, dislocation refers to a linear crystal defect included in a crystal.

The presence of dislocations in the piezoelectric film 13 can reduce or prevent the occurrence of cracking which is likely to occur in a single crystal, thus reducing or preventing peeling of the film from the substrate 11. This increases the manufacturing yield of the piezoelectric film 13.

A dislocation in a piezoelectric film can be determined by, for example, a TEM image as shown in FIG. 9A. As shown in the figure, a location can be determined, for example, by a site (dislocation line) where an atomic arrangement line (a straight chain line extending obliquely downward in a rightward direction in FIG. 9A) branches into two lines.

When a dislocation line is present in the cross-sectional direction (direction parallel or substantially parallel to the surface of the piezoelectric film) as shown in FIG. 9A, the dislocation can be determined by a TEM image as described above. On the other hand, when a dislocation line is present in the film thickness direction (direction perpendicular or substantially perpendicular to the surface of the piezoelectric film), the dislocation can be detected by an etch pit method, for example. The etch pit method is a method which involves immersing an object film in an etchant such as an acid or alkaline solution, for example, and can identify a site, where a recess has been formed due to preferential corrosion as compared to the surrounding area, as a dislocation site.

The piezoelectric film 13 may include, for example, a screw dislocation or a threading dislocation. As used herein, screw dislocation refers to a structure in which a dislocation line and Burger's vector are parallel or substantially parallel to each other, and a crystal plane is parallelly or substantially parallelly displaced from the dislocation line. Threading dislocation refers to a structure in which a dislocation line penetrates the c-plane.

Clear spots are observed in the electron diffraction image of FIG. 9B, indicating that a single crystal or a well-oriented polycrystal has been obtained.

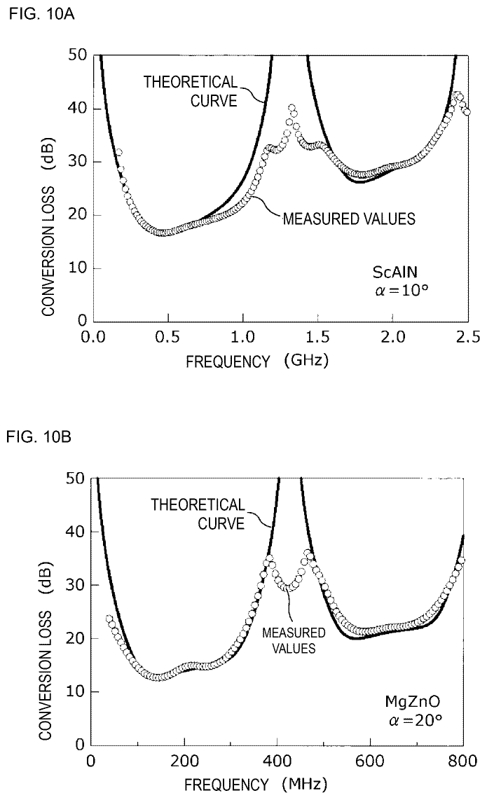

Next, a second conductive film 14 was formed on each of the two types of piezoelectric films 13 to produce a thin-film resonator, and a conversion loss of transversal wave due to thickness-shear vibration was measured by a network analyzer. FIG. 10A shows the measurement results for the piezoelectric film 13 of scandium aluminum nitride, and FIG. 10B shows the measurement results for the piezoelectric film 13 of magnesium zinc oxide. From a comparison between a conversion loss curve obtained and a theoretical curve of conversion loss calculated using Mason's equivalent circuit model, the electromechanical coupling coefficient k35² related to a thickness-shear vibration can be estimated to be about 0.72% for the piezoelectric film 13 of scandium aluminum nitride, and about 2.2% for the piezoelectric film 13 of magnesium zinc oxide. In this regard, the actual measurement values of conversion loss include a loss due to a factor(s) other than the actual conversion loss. Therefore, the actual electromechanical coupling coefficient k35² is considered to be higher than the estimated value.

### (2-3) Lead Titanate (PTO)

PTO has a perovskite crystal structure and has a four-fold rotational symmetry about the c-axis. While a piezoelectric film including PTO only generates a vibration in the thickness direction when the c-axis is oriented perpendicular or substantially perpendicular to the film, the film can generate a thickness-shear vibration when the c-axis is inclined from a direction perpendicular or substantially perpendicular to the film. In the present example embodiment, a piezoelectric film including PTO, in which the c-axis as a particular oriented crystal axis is inclined with respect to a direction perpendicular or substantially perpendicular to the film, was manufactured for use in a thin-film resonator that generates such a thickness-shear mode vibration. The aimed value of inclination angle α was set to about 25° (the c-axis as a particular substrate crystal axis is inclined by about 25° with respect to a normal to the substrate surface).

A substrate including a lanthanum-doped single crystal of strontium titanate (STO), having a perovskite crystal structure, was cut into a substrate 11 such that the c-axis (particular substrate crystal axis) was inclined by about 25° from a normal to the surface of the substrate 11. Such a lanthanum-doped substrate 11 itself has an electrical conductivity. Therefore, in the present example embodiment, the piezoelectric film 13 was formed directly on the substrate 11 without providing a conductive film 12. An RF magnetron sputtering apparatus was used to form the piezoelectric film 13. The film forming conditions are as follows.

### Piezoelectric Film 13 of PTO

A target, including a mixed powder of a PTO powder and a lead oxide (PbO) powder which were mixed such that the atomic ratio of lead and titanium was about 10:1 (about 10% excess lead atoms), was placed on the cathode, and a film was formed to a thickness of about 0.9 μm at a temperature of about 600° C. in a mixed gas atmosphere at a pressure of about 0.4 Pa while applying a radio-frequency power of about 100 W. The mixed gas was a mixture of argon gas and oxygen gas at a partial pressure ratio of about 25:1.

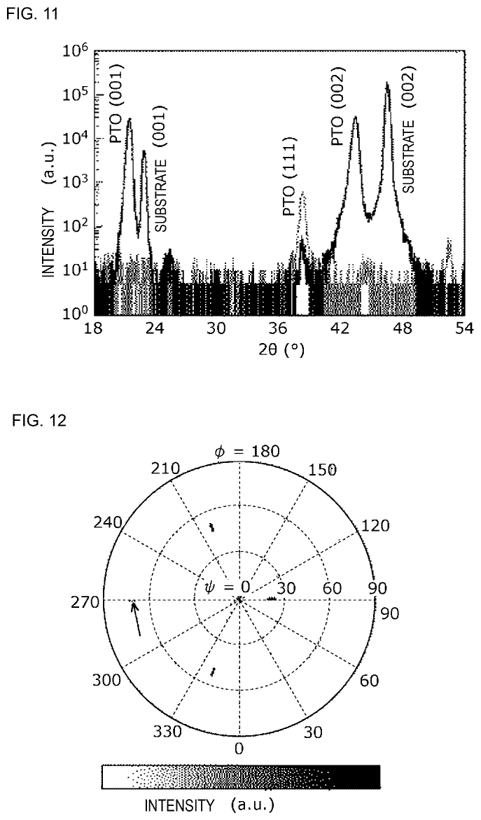

X-ray diffraction measurement was performed on the thus-manufactured piezoelectric film 13. First, a 2θ-ω scan was performed by a common measurement method at an incident angle θ of X-rays to the surface of the piezoelectric film 13. As shown in the gray X-ray diffraction chart of FIG. 11, a diffraction peak is seen for the (111) plane of PTO, whereas no diffraction peak is seen for the (001) plane or the (002) plane.

Next, the piezoelectric film 13 was tilted such that the incident angle of X-rays to the surface of the piezoelectric film 13 became θ+about 25°, and then a 2θ-ω scan was performed. As shown in the black X-ray diffraction chart of FIG. 11, diffraction peaks are seen for the (001) and (002) planes of PTO (diffraction peaks of the (001) and (002) planes of the crystal of the substrate 11 are also seen). This indicates that the c-axis of PTO is inclined at the same inclination angle α=about 250 as the aimed one with respect to a direction perpendicular or substantially perpendicular to the piezoelectric film 13.

Next, a pole figure for the (101) plane was obtained by X-ray diffractometry of the manufactured piezoelectric film 13. The pole figure is shown in FIG. 12. Four poles are seen which show a four-fold rotational symmetry about a point where the deflection angle Ψ is around 25° (one of the poles has a somewhat low intensity, and is shown by the arrow in FIG. 12). The pole figure indicates that the c-axis of PTO is inclined at an inclination angle α=about 25° with respect to a direction perpendicular or substantially perpendicular to the piezoelectric film 13, and is also oriented in a direction in a plane perpendicular or substantially perpendicular to the c-axis.

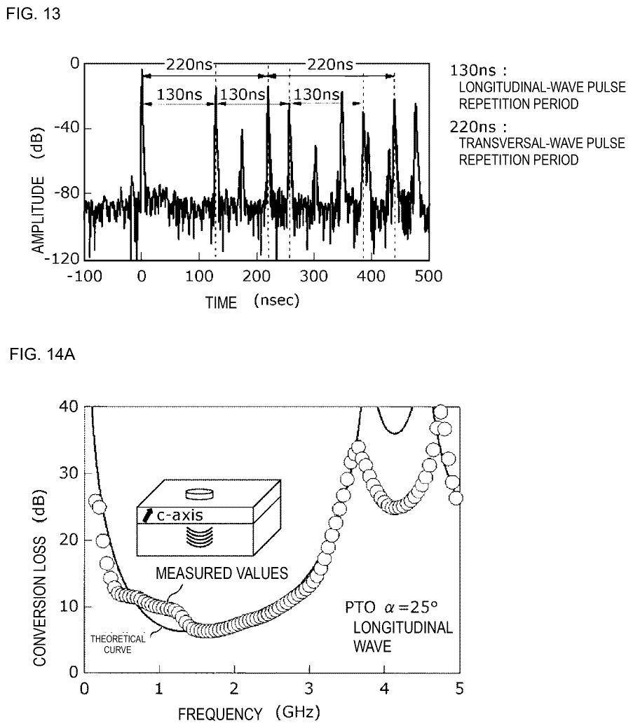

Next, a second conductive film 14 was formed on the manufactured piezoelectric film 13 to produce a thin-film resonator. The reflection coefficient S11 of the thin-film resonator was measured using a network analyzer, and an inverse Fourier transform was performed to calculate a time-domain impulse response. The impulse response refers to pulsed responses repeated over time caused by multiple reflections of pulsed ultrasonic waves, generated at a certain time, at both the front and back surfaces of the piezoelectric film of the thin-film resonator. The calculated impulse response is shown in FIG. 13. The impulse response has peaks repeated about every 130 nsec (nanoseconds), and peaks repeated about every 220 nsec. The former is considered to be due to longitudinal waves caused by a vibration in a direction perpendicular or substantially perpendicular to the film, and the latter is considered to be due to transversal waves caused by a thickness-shear vibration.

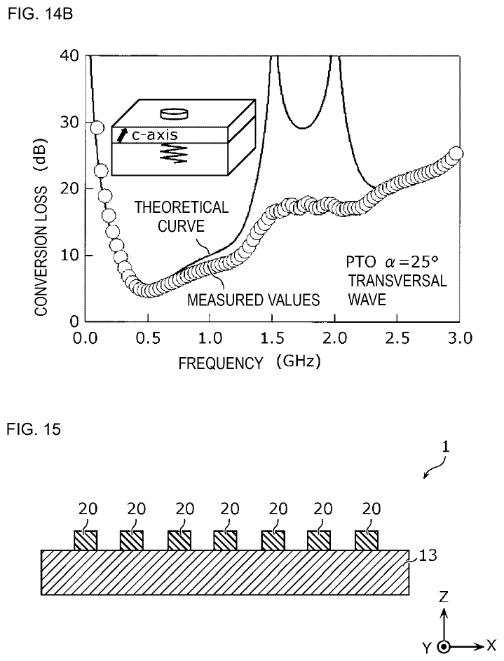

Next, a conversion loss of longitudinal wave and a conversion loss of transversal wave were measured for the thin-film resonator using a network analyzer. FIG. 14A shows the measurement results for the longitudinal wave, and FIG. 14B shows the measurement results for the transversal wave. From a comparison between a conversion loss curve obtained and a theoretical curve of conversion loss calculated using Mason's equivalent circuit model, the electromechanical coupling coefficient k33² related to a vibration in a direction perpendicular to the film can be estimated to be about 13.5%, and the electromechanical coupling coefficient k35² related to a thickness-shear vibration can be estimated to be about 17.9%.

The piezoelectric film 13 according to the present example embodiment may be a piezoelectric film including lithium tantalate. In that case, the piezoelectric film 13 grows epitaxially such that the particular oriented crystal axis (c-axis), which is a predetermined crystal axis, is inclined from a direction perpendicular or substantially perpendicular to the piezoelectric film 13.

The use of lithium niobate or lithium tantalate for the piezoelectric film 13 can achieve a high electromechanical coupling coefficient and good frequency-temperature characteristics.

In view of the fact that the piezoelectric film 13 according to the present example embodiment is formed using a sputtering method or the like, the piezoelectric film 13 may be doped with an impurity. Doping of an impurity into the piezoelectric film 13 may be performed by intentional addition (doping) of an impurity, or may be effected in an unintentional manner, i.e. by incidental inclusion of an impurity.

### Example Embodiment 2

Example embodiment 2 of the present invention illustrates the construction and high-frequency propagation characteristics of a piezoelectric device including a piezoelectric film 13 according to example embodiment 1.

FIG. 15 is a cross-sectional view of a Lamb wave device 1 according to example embodiment 2. The Lamb wave device 1 is an example of a piezoelectric device, and utilizes a Lamb wave (a type of plate wave) that propagates (in the X-axis direction of FIG. 15) in a piezoelectric film 13. The Lamb wave device 1 includes the piezoelectric film 13 and IDT (Interdigital Transducer) electrodes 20.

The piezoelectric film 13 is a piezoelectric film 13 according to example embodiment 1, and has been epitaxially grown such that the particular oriented crystal axis (c-axis), which is a predetermined crystal axis, is inclined from a direction (the Z-axis of FIG. 15) perpendicular or substantially perpendicular to the piezoelectric film 13 about the X-axis (toward the Y-axis of FIG. 15 by the second Euler angle b°). The piezoelectric film 13 includes, for example, lithium tantalate or lithium niobate.

The relationship between a main surface of the piezoelectric film 13 and the Euler angles (first Euler angle, second Euler angle, third Euler angle) expressing the propagation direction of Lamb waves will be described. Of the crystal axes (CX, CY, CZ (c-axis)) of the piezoelectric film 13, the CX axis is rotated counterclockwise about the CZ axis by the first Euler angle to obtain an Xa-axis. Next, the CZ axis is rotated counterclockwise about the Xa-axis by the second Euler angle to obtain a Z′-axis. The surface including the Xa-axis and having the Z′-axis as a normal line is the main surface of the piezoelectric film 13. The direction of an X′-axis, obtained by rotating the Xa-axis counterclockwise about the Z′-axis by the third Euler angle, is the propagation direction of Lamb waves. The X-axis in FIG. 15 corresponds to the X′-axis described above with reference to the Euler angles, and the Z-axis in FIG. 15 corresponds to the Z′-axis described above with reference to the Euler angles.

In a plan view of the piezoelectric film 13, the IDT electrodes 20 each include a pair of comb-shaped electrodes that face each other. Each of the pair of comb-shaped electrodes includes a plurality of electrode fingers that are parallel or substantially parallel to each other, and a busbar electrode connecting the electrode fingers. The electrode fingers are provided along a direction (Y-axis direction) perpendicular or substantially perpendicular to the propagation direction of acoustic waves (X-axis direction).

For the Lamb wave device 1 having the above-described construction, the electromechanical coupling coefficient k² was calculated when the first and third Euler angles of all the Euler angles (first Euler angle, second Euler angle b, third Euler angle) were set to about 0°, and the second Euler angle b was varied. In this calculation, the electrode duty of the IDT electrodes 20 was set to about 0.5, the wavelength λ (twice the pitch of adjacent electrode fingers) was set to about 1 μm, the film thickness of the IDT electrodes 20 was set to about 0.05λ, and the film thickness of the piezoelectric film 13 was set to about 0.15λ.

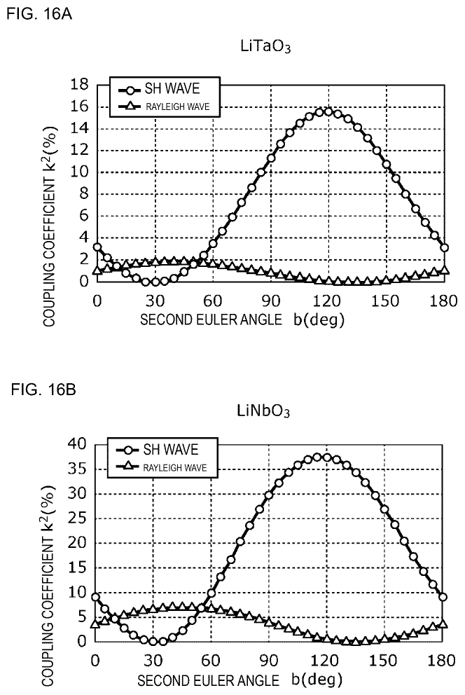

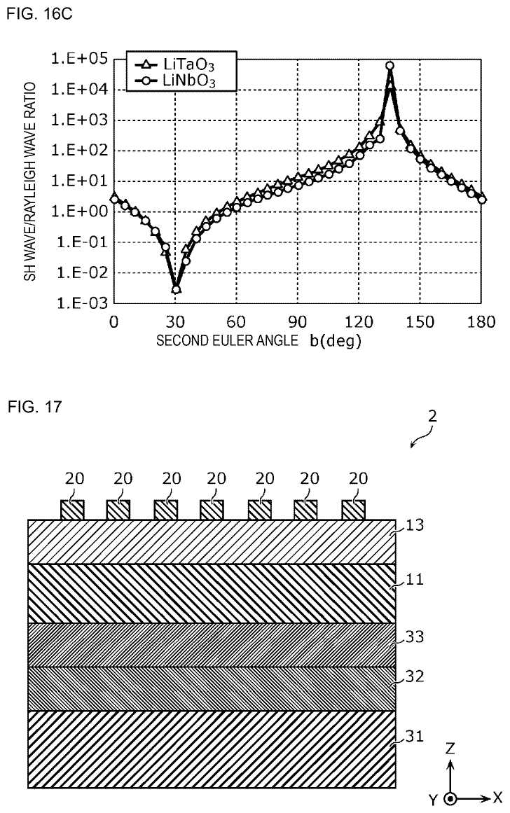

FIG. 16A is a graph showing the relationship between the second Euler angle b and the electromechanical coupling coefficient k² as observed when the piezoelectric film 13 of the Lamb wave device 1 according to example embodiment 2 is lithium tantalate. FIG. 16B is a graph showing the relationship between the second Euler angle b and the electromechanical coupling coefficient k² as observed when the piezoelectric film 13 of the piezoelectric device 1 according to example embodiment 2 is lithium niobate. FIG. 16C is a graph showing the relationship between the second Euler angle b and the SH wave/Rayleigh wave ratio in the piezoelectric device 1 according to example embodiment 2.

As shown in 16A, when the piezoelectric film 13 of the piezoelectric device 1 includes lithium tantalate, the electromechanical coupling coefficient k² of SH wave is higher than that of Rayleigh wave when the second Euler angle b is in the range of not less than about 0° and not more than about 10° and in the range of not less than about 55° and not more than about 180°. This indicates that when the piezoelectric film 13 includes lithium tantalate, an SH wave can be used as a main mode.

The data in FIG. 16C indicates that when the piezoelectric film 13 of the piezoelectric device 1 includes lithium tantalate, the second Euler angle b is preferably, for example, not less than about 100° and not more than about 160°. In particular, when the piezoelectric film 13 includes lithium tantalate, the use of the second Euler angle b in such a range can make the electromechanical coupling coefficient k² of SH wave about 200 times or more higher than the electromechanical coupling coefficient k² of Rayleigh wave.

The data in FIG. 16C also indicates that when the piezoelectric film 13 of the piezoelectric device 1 includes lithium tantalate, the second Euler angle b is more preferably, for example, not less than about 125° and not more than about 140°. In particular, when the piezoelectric film 13 includes lithium tantalate, the use of the second Euler angle b in such a range can make the electromechanical coupling coefficient k² of SH wave about 200 times or more higher than the electromechanical coupling coefficient k² of Rayleigh wave.

On the other hand, as shown in 16B, when the piezoelectric film 13 of the piezoelectric device 1 includes lithium niobate, the electromechanical coupling coefficient k² of SH wave is higher than that of Rayleigh wave when the second Euler angle b is in the range of not less than about 0° and not more than about 5° and in the range of not less than about 60° and not more than about 180°. This indicates that when the piezoelectric film 13 includes lithium niobate, SH wave can be used as a main mode.

The data in FIG. 16C indicates that when the piezoelectric film 13 of the piezoelectric device 1 includes lithium niobate, the second Euler angle b is preferably, for example, not less than about 110° and not more than about 155°. In particular, when the piezoelectric film 13 includes lithium niobate, the use of the second Euler angle b in such a range can make the electromechanical coupling coefficient k² of SH wave about 20 times or more higher than the electromechanical coupling coefficient k² of Rayleigh wave.

The data in FIG. 16C also indicates that when the piezoelectric film 13 of the piezoelectric device 1 includes lithium niobate, the second Euler angle b is more preferably, for example, not less than about 130° and not more than about 140°. In particular, when the piezoelectric film 13 includes lithium niobate, the use of the second Euler angle b in such a range can make the electromechanical coupling coefficient k² of SH wave about 200 times or more higher than the electromechanical coupling coefficient k² of Rayleigh wave.

While the first Euler angle and the third Euler angle are set to about 0° in the above-described setting of the Euler angles of the piezoelectric film 13, the first Euler angle and the third Euler angle need not be strictly 0°. Substantially the same advantageous effects will be achieved if the first and third Euler angles are within the range of about 0°±10°.

A piezoelectric device 2, which includes a laminate of a piezoelectric film 13 according to example embodiment 1 and a substrate 11, will now be described.

FIG. 17 is a cross-sectional view of a piezoelectric device 2 according to a variation of example embodiment 2. The piezoelectric device 2 includes a piezoelectric film 13, a substrate 11, a low acoustic velocity layer 33, a high acoustic velocity layer 32, a support substrate 31, and IDT electrodes 20.

The piezoelectric film 13 is a piezoelectric film 13 according to example embodiment 1, and has epitaxially grown such that the particular oriented crystal axis (c-axis), which is a predetermined crystal axis, is inclined from a direction (Z-axis) perpendicular or substantially perpendicular to the piezoelectric film 13 about the X-axis (toward the Y-axis by the second Euler angle b°). The piezoelectric film 13 includes, for example, lithium tantalate or lithium niobate.

The substrate 11 is a substrate 11 according to example embodiment 1, and is an insulating layer which is in contact with the piezoelectric film 13 and includes a monocrystalline or polycrystalline insulating material having the same or substantially the same rotational symmetry about a predetermined crystal axis as a rotational symmetry about the particular oriented crystal axis (c-axis). The predetermined crystal axis has the same or substantially the same inclination as the inclination of the particular oriented crystal axis.

The substrate 11 includes an insulating material such as, for example, sapphire, silicon carbide, lithium tantalate, or lithium niobate. The contact of the piezoelectric film 13 with the substrate 11 which is an insulating layer can improve and optimize the elasticity, the dielectric properties, and their temperature dependences of the piezoelectric film 13.

The use of a piezoelectric material, such as, for example, lithium tantalate or lithium niobate, for the substrate 11 can improve and optimize the piezoelectricity and its temperature dependence of the piezoelectric film 13.

The substrate 11 may be, for example, a semiconductor layer which is in contact with the piezoelectric film 13 and includes a monocrystalline or polycrystalline semiconductor material having the same or substantially the same rotational symmetry about a predetermined crystal axis as a rotational symmetry about the particular oriented crystal axis (c-axis). The predetermined crystal axis has the same or substantially the same inclination as the inclination of the particular oriented crystal axis. The semiconductor material is, for example, silicon.

The support substrate 31 supports the high acoustic velocity layer 32, the low acoustic velocity layer 33, the substrate 11, the piezoelectric film 13, and the IDT electrodes 20.

Examples of materials usable for the support substrate 31 include piezoelectric materials such as aluminum nitride, lithium tantalate, lithium niobate, or quartz, ceramic materials such as alumina, sapphire, magnesia, silicon nitride, silicon carbide, zirconia, cordierite, mullite, steatite, or forsterite, dielectric materials such as diamond or glass, semiconductor materials such as silicon or gallium nitride, or resins. A material including such a material as a main component can also be used.

The low acoustic velocity layer 33 is disposed between the substrate 11 and the support substrate 31, and in which the acoustic velocity of bulk waves is lower than that of bulk waves propagating in the piezoelectric film 13. Acoustic waves have the property of their energy concentrating in a medium with low acoustic velocity. Therefore, the low acoustic velocity layer 33 can reduce or prevent leakage of the energy of surface acoustic waves out of the piezoelectric film 13.

Examples of materials usable for the low acoustic velocity layer 33 include dielectric materials such as glass, silicon oxide, silicon oxynitride, lithium oxide, tantalum oxide, or a compound of silicon oxide with fluorine, carbon, or boron added. A material including such a material as a main component can also be used.

The high acoustic velocity layer 32 is disposed between the low acoustic velocity layer 33 and the support substrate 31, and in which the acoustic velocity of propagating bulk waves is higher than the acoustic velocity of acoustic waves propagating in the piezoelectric film 13.

Examples of materials usable for the high acoustic velocity layer 32 include piezoelectric materials such as aluminum nitride, lithium tantalate, lithium niobate, or quartz, ceramic materials such as alumina, sapphire, magnesia, silicon nitride, silicon carbide, zirconia, cordierite, mullite, steatite, forsterite, spinel, or sialon, dielectric materials such as aluminum oxide, silicon oxynitride, DLC (diamond-like carbon), or diamond, or semiconductor materials such as silicon. A material including such a material as a main component can also be used. The spinel includes, for example, an aluminum compound including oxygen and one or more of Mg, Fe, Zn, Mn, etc. Examples of the spinel include MgAl₂O₄, FeAl₂O₄, ZnAl₂O₄, or MnAl₂O₄.

The piezoelectric device 2 according to this variation only needs to include the piezoelectric film 13, the substrate 11, and the IDT electrodes 20, and need not necessarily include at least one of the low acoustic velocity layer 33, the high acoustic velocity layer 32, and the support substrate 31.

The piezoelectric device 2 according to this variation may include the piezoelectric film 13, the substrate 11, the IDT electrodes 20, the support substrate 31, and an energy confining layer. In that case, the piezoelectric device 2 has a structure in which the support substrate 31, the energy confining layer, the substrate 11, the piezoelectric film 13, and the IDT electrodes 20 are laminated in this order.

The energy confining layer includes a single layer or multiple layers. The velocity of bulk acoustic waves propagating in at least one of the layers is higher than the velocity of acoustic waves propagating in the vicinity of the piezoelectric film 13. The energy confining layer may have, for example, a laminated structure including a low acoustic velocity layer and a high acoustic velocity layer. Alternatively, the energy confining layer may be an acoustic impedance layer having a structure in which low acoustic impedance layers having a relatively low acoustic impedance and high acoustic impedance layers having a relatively high acoustic impedance are laminated alternately.

According to the piezoelectric device 2 of this variation, the piezoelectricity and its temperature dependence of the piezoelectric film 13 can be improved and optimized.

While the present invention has been described with reference to example embodiments, the present invention is not limited to the example embodiments. Changes and modifications may be made to the example embodiments without departing from the spirit and scope of the present invention.

The rotational symmetries of the substrate 11 and the piezoelectric film 13 can be obtained by, for example, the following method. Pole measurement is performed by XRD. When a diffraction peak obtained is corrected by an inclination of an axis, a pole figure with a rotational symmetry with respect to the center appears. Upon measurement of such a pole figure for each of the substrate 11 and the piezoelectric film 13, the rotational symmetry of each of the substrate 11 and the piezoelectric film 13 can be obtained. Further, by locally using TEM or SEM, an electron beam diffraction pattern corresponding to the symmetry of a crystal structure can be obtained. The rotational symmetry can be measured with high accuracy by analyzing the diffraction pattern.

The inclinations of the particular oriented crystal axis and the particular substrate crystal axis can be obtained using XRD or electron-beam diffractometry such as TEM or SEM, for example. In XRD, for example, such an inclination can be obtained from an angle which is corrected so as to make a pole figure with a rotational symmetry with respect to the center. In TEM or SEM, such an inclination can be obtained by analyzing an electron beam diffraction pattern obtained.

The inclination angles of the particular oriented crystal axis and the particular substrate crystal axis are defined as being the same or substantially the same when the difference between the inclination angles is within the range of about ±16°, regardless of the directions of the inclinations. The difference between the inclination angles is preferably within the range of about ±5°, for example. A misalignment between the inclination of the particular substrate crystal axis of the substrate 11 and the inclination of the particular oriented crystal axis of the piezoelectric film 13 causes an increase in the lattice misfit at the interface between the piezoelectric film 13 and the substrate 11. The increase in the lattice misfit is about 4% or less when the difference between the inclination angles is within about ±16°, while the increase in the lattice misfit is about 0.4% or less and thus is little influential when the difference between the inclination angles is within about ±5°.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A method for manufacturing a piezoelectric film including a monocrystalline or polycrystalline piezoelectric material in which a particular oriented crystal axis is inclined from a direction perpendicular to the film, the method comprising:
preparing a substrate including a single crystal with a same or substantially a same rotational symmetry about a particular substrate crystal axis as a rotational symmetry about the particular oriented crystal axis in the piezoelectric material, the particular substrate crystal axis including a same or substantially a same inclination as an inclination of the particular oriented crystal axis; and
forming a piezoelectric film including the piezoelectric material on the substrate by an epitaxial process.

2. The method for manufacturing a piezoelectric film according to claim 1, further comprising between the preparing the substrate and the forming the piezoelectric film, forming a conductive film including a conductive material having the same or substantially the same rotational symmetry about a predetermined crystal axis as a rotational symmetry about the particular substrate crystal axis, on a surface of the substrate by an epitaxial process.

3. A piezoelectric film comprising:
an epitaxially grown piezoelectric film including a particular oriented crystal axis inclined from a direction perpendicular or substantially perpendicular to the film.

4. The piezoelectric film according to claim 3, wherein the epitaxially grown piezoelectric film includes a crystal dislocation.

5. The piezoelectric film according to claim 3, wherein the epitaxially grown piezoelectric film includes lithium niobate or lithium tantalate.

6. The piezoelectric film according to claim 3, wherein
the epitaxially grown piezoelectric film is in contact with a conductive film including a monocrystalline or polycrystalline conductive material having a same or substantially a same rotational symmetry about a predetermined crystal axis as a rotational symmetry about the particular oriented crystal axis; and
the predetermined crystal axis has the same inclination as the inclination of the particular oriented crystal axis.

7. The piezoelectric film according to claim 3, wherein polarization components perpendicular or substantially perpendicular to the epitaxially grown piezoelectric film are directed in opposite directions between one surface side and another surface side of the epitaxially grown piezoelectric film piezoelectric film.

8. A piezoelectric device comprising:
the piezoelectric film according to claim 3.

9. The piezoelectric device according to claim 8, further comprising:
an insulating layer in contact with the piezoelectric film and including a monocrystalline or polycrystalline insulating material having the same rotational symmetry about a predetermined crystal axis as a rotational symmetry about the particular oriented crystal axis; wherein
the predetermined crystal axis has the same inclination as the inclination of the particular oriented crystal axis.

10. The piezoelectric device according to claim 8, further comprising:
a semiconductor layer in contact with the piezoelectric film and including a monocrystalline or polycrystalline semiconductor material having the same rotational symmetry about a predetermined crystal axis as a rotational symmetry about the particular oriented crystal axis; wherein
the predetermined crystal axis has the same inclination as the inclination of the particular oriented crystal axis.

11. The piezoelectric device according to claim 9, further comprising:
a support substrate;
a low acoustic velocity layer between the insulating layer and the support substrate, in which an acoustic velocity of bulk waves is lower than that of bulk waves propagating in the piezoelectric film; and
a high acoustic velocity layer between the low acoustic velocity layer and the support substrate, in which an acoustic velocity of propagating bulk waves is higher than an acoustic velocity of acoustic waves propagating in the piezoelectric film.

12. The piezoelectric device according to claim 9, wherein the insulating layer includes lithium niobate or lithium tantalate.

13. The piezoelectric device according to claim 8, wherein the piezoelectric device defines one of a solidly mounted resonator device, a film bulk acoustic resonator device, an excited bulk wave resonator device, a surface acoustic wave device, or a Lamb wave device.

14. The piezoelectric device according to claim 8, wherein
the piezoelectric device defines a Lamb wave device;
the piezoelectric film includes lithium tantalate; and
a second Euler angle of the piezoelectric film is not less than about 0° and not more than about 10°, or not less than about 55° and not more than about 180°.

15. The piezoelectric device according to claim 14, wherein the second Euler angle of the piezoelectric film is not less than about 100° and not more than about 160°.

16. The piezoelectric device according to claim 14, wherein the second Euler angle of the piezoelectric film is not less than about 125° and not more than about 140°.

17. The piezoelectric device according to claim 8, wherein
the piezoelectric device defines a Lamb wave device;
the piezoelectric film includes lithium niobate; and
a second Euler angle of the piezoelectric film is not less than about 0° and not more than about 5°, or not less than about 60° and not more than about 180°.

18. The piezoelectric device according to claim 17, wherein the second Euler angle of the piezoelectric film is not less than about 110° and not more than about 155°.

19. The piezoelectric device according to claim 17, wherein the second Euler angle of the piezoelectric film is not less than about 130° and not more than about 140°.
